(19) United States
(12) Patent Application Publication
(10) Pub. No.: US 2006/0098095 A1
(43) Pub. Date: May 11, 2006

(54) Method of compensating for the effect of undersirable attributes on the measurement of desirable attributes for objective image quality

(76) Inventor: Karl Wittig, New York, NY (US)

Correspondence Address: PHILIPS INTELLECTUAL PROPERTY & STANDARDS, P.O. BOX 3001, BRIARCLIFF MANOR, NY, 10510, US

(21) Appl. No.: 10/545,843

(22) PCT Filed: Dec. 10, 2003
(86) PCT No.: PCT/IB03/05873

§ 371 Date: Aug. 17, 2005

Related U.S. Application Data
(60) Provisional application No. 60/434,591, filed on Dec. 18, 2002.

(51) Int. Cl. G01R 29/26

(52) U.S. Cl. 348/180; 702/69

(57) ABSTRACT

A method and apparatus for compensating for the effect of improperly characterizing first image attribute as enhancing a second image attribute during objective image quality measurement of the second image attribute in a video. The method and apparatus determines (10) a quantitative relationship between an objective image quality metric for the first image attribute and an objective image quality metric for the second image attribute; and uses the determined quantitative relationship to compensate (40) the objective image quality metric of the second image attribute for the effects of the first image attribute. Also, a video processing system for automated optimization of video image quality. The system includes a video processing device, which utilizes the present invention, for generating an objective image quality metric. The objective image quality metric is utilized by a video optimization device to adjust parameters of a video enhancement device of the system, which enhances digitized versions of videos.

### FIELD OF THE INVENTION

This invention relates to video processing and more particularly to a method and apparatus that compensates for the effect of improperly characterizing an undesirable image attribute as enhancing a desirable image attribute during objective image quality measurement of the desirable image attribute. The invention also relates to a video processing system for automated optimization of video image quality.

### BACKGROUND OF THE INVENTION

Objective image quality determination generally consists of measuring individual image attributes, or “metrics”, and combining these in some prescribed manner to produce composite metric which is a measure of the overall image quality. Some of the attributes typically used are desirable, such as image contrast or, at least within a restricted range, image sharpness. Other attributes, however, such as image noise, clipping, or the block impairments that result from “lossy” digital video encoding with data compression and decompression, are clearly undesirable and therefore, must contribute to the combined image quality metric in the opposite sense from the desirable attributes. Theoretically, the existence of both desirable and undesirable attributes should not create any problems in image quality measurement as long as every attribute can be unambiguously categorized as either desirable or undesirable.

In practice, however, it is possible and even commonplace for an attribute in a first category to affect the measurement of an attribute in another or second category and, in particular, to do so by increasing the measured value of the attribute in the second category. This produces a higher value for the metric corresponding to attribute of the second category, which in turn increases the value of the composite metric. For example, image noise, which is an unambiguously undesirable attribute, has some image characteristics that are similar to those used for the measurement of image sharpness, which is generally considered a desirable attribute. Hence, a noisy image, whose overall appearance is less than high quality, may be improperly characterized as being a very sharp image, whose overall appearance is high quality. When this occurs, the resulting image quality measurement for the noisy image will be higher than actually merited.

Accordingly, a method is needed which addresses the effect of one image attribute on the measurement of another image attribute.

### SUMMARY OF THE INVENTION

The present invention compensates for the effect of improperly characterizing a first image attribute as enhancing a second image attribute during objective image quality measurement of the second image attribute in a video. The invention comprises determining a quantitative relationship between an objective image quality metric for the first image attribute and an objective image quality metric for the second image attribute; and using the determined quantitative relationship to compensate the objective image quality metric of the second image attribute for the effects of the first image attribute.

One aspect of the invention includes a video processing system for automated optimization of video image quality. The system includes a video processing device, which utilizes the present invention, for generating a composite objective image quality metric. The composite objective image quality metric is utilized by a video optimization device to adjust parameters of a video enhancement device of the system, which enhances digitized versions of videos.

### BRIEF DESCRIPTION OF THE DRAWINGS

FIG. 1 is a block diagram representing the basic steps of the method of the present invention.

FIG. 2 is a block diagram illustrating the method of the present invention as applied to the formation of a composite OIQ metric for objective image quality determination.

FIG. 3 is a block diagram of an exemplary video processing system, which utilizes the method of the present invention for automated optimization of video image quality.

### DETAILED DESCRIPTION

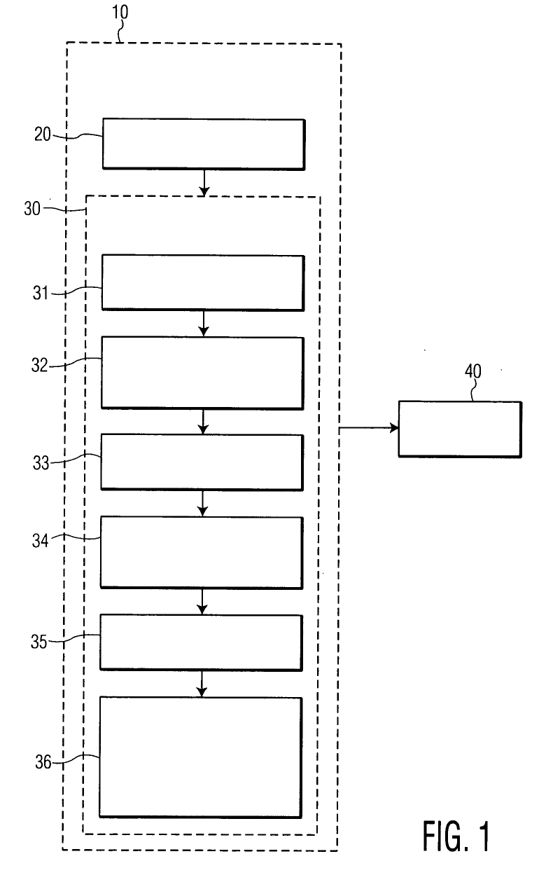

The present invention is a method of compensating for the effect of improperly characterizing an undesirable image attribute as enhancing a desirable image attribute during objective image quality measurement of the desirable image attribute. Referring now to the drawings, and initially to FIG. 1, there is shown a block diagram representing the basic steps involved in the method. In block 10, a quantitative relationship is determined between an objective image quality (OIQ) metric value measured for a first image attribute (FIA) and an objective image quality (OIQ) metric value measured for a second image attribute (SIA). In block 40, the determined relationship is then used to compensate the SIA for the undesired effects of the FIA.

Still referring to FIG. 1, there are two basic steps for determining the quantitative relationship between the measured OIQ metric value for the FIA and the measured OIQ metric value for the SIA. These steps comprise in block 20 introducing one or more known, controlled amounts of the FIA into the video sequence of interest and in block 30 ascertaining the effects of introducing the known, controlled amounts of the FIA on the OIQ metric measurements for the FIA and the SIA.

The step in block 30 for ascertaining the effects of introducing the known, controlled amount of the FIA on the OIQ metric measurements for the FIA and the SIA may be performed as follows. In block 31, OIQ metric measurements for the FIA are conventionally performed for two or more known values of the FIA and these measurements are used in block 32 to determine the numerical relationship between the FIA value and its OIQ metric measurement value. In block 33, OIQ metric measurements for the SIA are performed for the same two or more values of the FIA and these measurements are used in block 34 to determine the numerical relationship between the FIA value and the SIA OIQ metric measurement value. In block 35, the numerical relationship determined in block 32 between the FIA value and that of its OIQ metric is reorganized as an inverse numerical relationship. In block 36, the inverse numerical relationship established in block 35 is used as the FIA value in block 34 to provide the relationship between the SIA OIQ metric and the FIA OIQ metric.

Assuming that the effects of the first and second image attributes combine in a linear manner for the measurement of the SIA (a reasonable approximation even when not entirely accurate), the relationship determined between the SIA OIQ metric and the FIA OIQ metric in block 10 is then used to compensate the SIA for the undesired effects of the FIA in block 40.

The following example illustrates, without limitation, the use of the present invention to compensate for the effect of image noise (undesirable) on image sharpness (desirable). One of ordinary skill in the art will of course appreciate that the present invention can be used to compensate for the effect of an image attribute of any one category on the measurement of an image attribute in any other category. For example, the present invention can also be used to compensate for the effect of block impairments (undesirable) on image sharpness (desirable) measurement. In another example, the present invention can be used to compensate for the effect of clipping artifacts (undesirable) on image contrast (desirable) measurement.

Continuing with the image noise/image sharpness example from above, two or more known levels or amounts of image noise may be introduced into a video sequence. The OIQ metric values of the image noise and sharpness measurements for each of these noise levels are then used to determine a first relationship between the image noise value and the image noise OIQ metric value, and a second relationship between the image noise value and the image sharpness OIQ metric value. The first relationship is given by the following equation:
Mₙₒᵢₛₑ=Rₙₒᵢₛₑ(noise)

This relationship simply quantifies the value of the image noise metric Mₙₒᵢₛₑ as a function of the image noise level noise. If the relation Rₙₒᵢₛₑ is known a priori, either theoretically or practically from the design of the noise measurement algorithm, its determination may not even be necessary. In any case, what is needed is the inverse of this relationship, which can be readily obtained, and is given by:
Noise=Rₙₒᵢₛₑ⁻¹(Mₙₒᵢₛₑ)

Since only the image noise level is varied, while the actual image sharpness of the video sequence remains constant, the above-mentioned second relationship between the image noise level and the image sharpness metric value for constant sharpness results. This gives the undesired contribution of the image noise to the value of the sharpness metric:
Mₛₕₐᵣₚ^{corr}=Rₛₕₐᵣₚ(noise)

The inverse of the first relationship is then substituted into the second relationship, which gives a relationship between the image noise contributions to the image sharpness metric and the image noise metric determined for that sequence:
Mₛₕₐᵣₚ^{corr}=Rₛₕₐᵣₚ[Rₙₒᵢₛₑ⁻¹(Mₙₒᵢₛₑ)]

This serves as the correction that is subtracted from the measured sharpness metric for the sequence, giving a measure of the actual image sharpness by itself:
Mₛₕₐᵣₚ^{comp}=Mₛₕₐᵣₚ^{meas}−Mₛₕₐᵣₚ^{corr}
Mₛₕₐᵣₚ^{comp}=Mₛₕₐᵣₚ^{meas}−Rₛₕₐᵣₚ[Rₙₒᵢₛₑ⁻¹(Mₙₒᵢₛₑ^{meas})]

In the case where the relationship between the FIA and SIA metric is linear, and the composite metric is also a linear combination of the various component image attribute metrics weighted by a set of predetermined coefficients, the linear relationships insure that this compensation is implicitly performed if the aforementioned coefficients were determined so that the resulting composite metric accurately corresponds to actual subjective evaluations of the image quality. However, in the event that either relationship is not linear, the effects of the first attribute on the second metric are not implicitly compensated. Consequently, an explicit compensation as described herein will result in a more accurate determination of the component metrics and, more important, of the resulting composite metric. This is especially true if the composite metric is obtained by any known means other than a simple weighted sum of the component metrics.

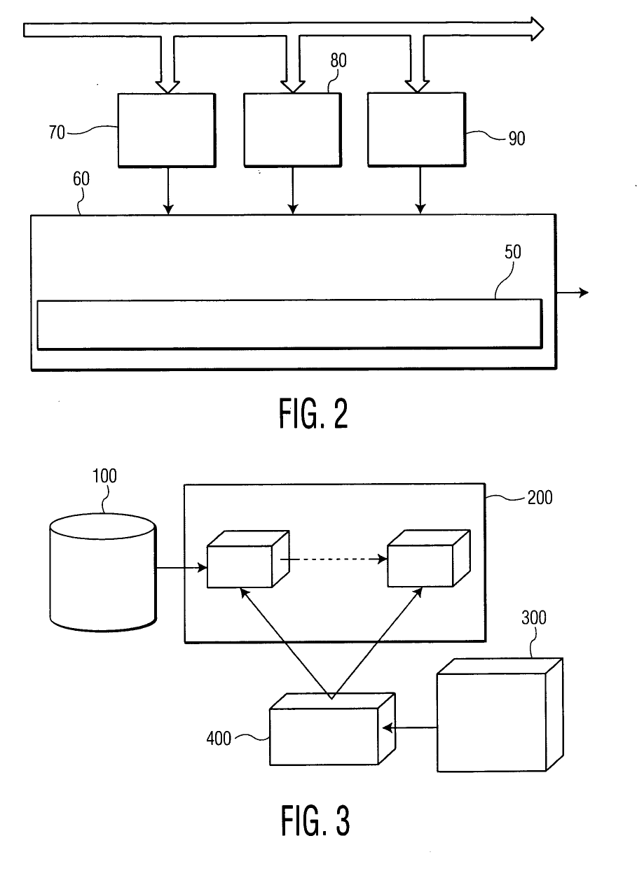

FIG. 2 is a block diagram illustrating the method of the present invention as applied to the formation of a composite OIQ metric for objective image quality determination. As illustrated, the method, denoted by block 50, may be used in any OIQ composite metric formation of block 60 for which one or more component OIQ metrics 70, 80, 90 are affected by image attributes other than those that they were designed to measure.

FIG. 3 is a block diagram of an exemplary video processing system, which utilizes the method of the present invention for automated optimization of video image quality. Block 100 represents a memory medium for storing digitized versions of videos. Block 200 represents a first video processing device that performs a chain of video enhancement functions fi-fN on the digitized versions of the videos stored in the memory medium of block 100. Such functions may include, for example but not limitation, image sharpness enhancement, image contrast enhancement, image noise reduction, and the like.

The image quality of the enhanced video output of the first video processing device of block 200 is objectively determined by a second video processing device in block 300, which performs the objective image quality determination method of the present invention, as described above in FIGS. 1 and 2. The composite OIQ metric generated at the output of the second video processing device of block 300 is used by a genetic algorithm of an image optimization device represented by block 400 to adjust the parameters of one or more of the constituent enhancement functions in the first video processing device of block 200, thereby maximizing the image quality of the enhanced video.

While the foregoing invention has been described with reference to the above embodiments, various modifications and changes can be made without departing from the spirit of the invention. Accordingly, such modifications and changes are considered to be within the scope of the appended claims.

1. A method of compensating for the effect of improperly characterizing a first image attribute as enhancing a second image attribute during objective image quality measurement of the second image attribute in a video, the method comprising the steps of:
determining a quantitative relationship between an objective image quality metric for the first image attribute and an objective image quality metric for the second image attribute; and
using the determined quantitative relationship to compensate the objective image quality metric of the second image attribute for the effects of the first image attribute.

2. The method according to claim 1, wherein the using the determined quantitative relationship step includes the steps of:
introducing known amounts of the first image attribute into the video; and
ascertaining effects of the known amounts of the first image attribute on an objective image quality metric for the first image attribute and the objective image quality metric for the second image attribute.

3. The method according to claim 2, wherein the ascertaining step includes the steps of:
measuring a value of the objective image quality metric for the first image attribute for each of the known amounts of the first image attribute; and
using the measured values of the objective image quality metric for the first image attribute to determine a numerical relationship between the first image attribute and the objective image quality metric for the first image attribute.

4. The method according to claim 3, wherein the ascertaining step further includes the steps of:
measuring a value of the objective image quality metric for the second image attribute for each of the known amounts of the first image attribute; and
using the measured values of the objective image quality metric for the second image attribute to determine the numerical relationship between the first image attribute and the objective image quality metric for the second image attribute.

5. The method according to claim 4, wherein the ascertaining step further includes the step of inversing the numerical relationship between the first image attribute and the objective image quality metric for the first image attribute.

6. The method according to claim 5, wherein the ascertaining step further includes the step of using the inverse numerical relationship between the first image attribute and the objective image quality metric for the first image attribute, as the first image attribute, to provide the quantitative relationship between the objective image quality metric for the first image attribute and the objective image quality metric for the second image attribute.

7. An apparatus for compensating for the effect of improperly characterizing a first image attribute as enhancing a second image attribute during objective image quality measurement of the second image attribute in a video, the apparatus comprising:
means for determining a quantitative relationship between an objective image quality metric for the first image attribute and an objective image quality metric for the second image attribute; and
means using the determined quantitative relationship, for compensating the objective image quality metric of the second image attribute for the effects of the first image attribute.

8. The apparatus according to claim 7, wherein the compensating means includes:
means for introducing known amounts of the first image attribute into the video; and
means for ascertaining effects of the known amounts of the first image attribute on an objective image quality metric for the first image attribute and the objective image quality metric for the second image attribute.

9. The apparatus according to claim 8, wherein the ascertaining means includes:
means for measuring a value of the objective image quality metric for the first image attribute for each of the known amounts of the first image attribute; and
means using the measured values of the objective image quality metric for the first image attribute for determining a numerical relationship between the first image attribute and the objective image quality metric for the first image attribute.

10. The apparatus according to claim 9, wherein the ascertaining means further includes;
means for measuring a value of the objective image quality metric for the second image attribute for each of the known amounts of the first image attribute; and
means using the measured values of the objective image quality metric for the second image attribute to determine a numerical relationship between the first image attribute and the objective image quality metric for the second image attribute.

11. The apparatus according to claim 10, wherein the ascertaining means further includes means for inversing the numerical relationship between the first image attribute and the objective image quality metric for the first image attribute.

12. The apparatus according to claim 11, wherein the ascertaining means further includes means, using the inverse numerical relationship between the first image attribute and the objective image quality metric for the first image attribute, as the first image attribute, to provide the quantitative relationship between the objective image quality metric for the first image attribute and the objective image quality metric for the second image attribute.

13. A memory medium for compensating for the effect of improperly characterizing a first image attribute as enhancing a second image attribute during objective image quality measurement of the second image attribute in a video, the memory medium comprising:
code for determining a quantitative relationship between an objective image quality metric for the first image attribute and an objective image quality metric for the second image attribute; and
code for compensating the objective image quality metric of the second image attribute for the effects of the first image attribute, using the determined quantitative relationship.

14. The memory medium according to claim 13, wherein the code for compensating includes:
code for introducing known amounts of the first image attribute into the video; and
code for ascertaining effects of the known amounts of the first image attribute on an objective image quality metric for the first image attribute and the objective image quality metric for the second image attribute.

15. The memory medium according to claim 14, wherein the code for ascertaining includes:
code for measuring a value of the objective image quality metric for the first image attribute for each of the known amounts of the first image attribute; and
code using the measured values of the objective image quality metric for the first image attribute for determining a numerical relationship between the first image attribute and the objective image quality metric for the first image attribute.

16. The memory medium according to claim 15, wherein the code ascertaining further includes;
code for measuring a value of the objective image quality metric for the second image attribute for each of the known amounts of the first image attribute; and
code using the measured values of the objective image quality metric for the second image attribute to determine a numerical relationship between the first image attribute and the objective image quality metric for the second image attribute.

17. The memory medium according to claim 16, wherein the code for ascertaining further includes code for inversing the numerical relationship between the first image attribute and the objective image quality metric for the first image attribute.

18. The memory medium according to claim 17, wherein the code for ascertaining further includes code, using the inverse numerical relationship between the first image attribute and the objective image quality metric for the first image attribute, as the first image attribute, to provide the quantitative relationship between the objective image quality metric for the first image attribute and the objective image quality metric for the second image attribute.

19. A video processing system for automated optimization of video image quality, the system comprising:
first processing means for performing video enhancement functions on a digitized version of the video and outputting an enhanced digitized video;
second processing means for:
determining a quantitative relationship between an objective image quality metric for a first image attribute and an objective image quality metric for a second image attribute;
using the determined quantitative relationship to compensate the objective image quality metric of the second image attribute for the effects of the first image attribute; and
forming a composite objective image quality metric from the objective image quality metrics of the first and second image attributes;
optimization means for adjusting parameters of at least one of the video enhancement functions performed by the first processing means in accordance with the composite objective image quality metric.

20. The video processing system according to claim 19, wherein the composite objective image quality metric is formed from the objective image quality metrics of the first and second image attributes and at least a third image attribute.
